(19) United States
(12) Patent Application Publication
(10) Pub. No.: US 2016/0035420 A1
(43) Pub. Date: Feb. 4, 2016

(54) NONVOLATILE MEMORY DEVICE AND METHOD FOR CONTROLLING SAME

(71) Applicant: Kabushiki Kaisha Toshiba, Minato-ku (JP)

(72) Inventors: Takuya KONNO, Yokkaichi (JP); Kikuko Sugimae, Kuwana (JP); Masayuki Ichige, Yokkaichi (JP)

(73) Assignee: Kabushiki Kaisha Toshiba, Minato-ku (JP)

(21) Appl. No.: 14/641,967

(22) Filed: Mar. 9, 2015

Related U.S. Application Data
(60) Provisional application No. 62/030,663, filed on Jul. 30, 2014.

(51) Int. Cl. G11C 13/00

(52) U.S. Cl. CPC G11C 13/0097; G11C 13/0069

(57) ABSTRACT

According to one embodiment, a device includes: word lines extending in a first direction, widths of the word lines in a second direction intersecting the first direction having a first width and a second width greater than the first width; bit lines provided above or under the word lines, the bit lines extending in the second direction, widths of the bit lines in the first direction having a third width and a forth width greater than the third width; storage elements; and a control circuit applying a potential for at least one of a plurality of non-selected word lines and a plurality of non-selected bit lines other than a selected word line and a selected bit line connected to a selected storage element, among the word lines and the bit lines, the potential applied thereto according to a width thereof.

### CROSS-REFERENCE TO RELATED APPLICATIONS

This application is based upon and claims the benefit of priority from U.S. Provisional Patent Application 62/030,663 filed on Jul. 30, 2014; the entire contents of which are incorporated herein by reference.

### FIELD

Embodiments described herein relate generally to a nonvolatile memory device and a method for controlling the same.

### BACKGROUND

In a three-dimensional nonvolatile memory device, there is a case where plural word lines and plural bit lines are respectively arranged to intersect each other and storage elements are arranged at positions where the word lines and the bit lines intersect each other.

However, if the plural word lines having the same line width and the same pitch are formed by a lithography technique and an etching technique, loss of periodicity may occur in an end part of groups of the plural arranged word lines, and thus, variation may occur in the line widths or the pitch of the word lines in the end part.

If the line widths of the word lines become larger than a target value or the pitch thereof becomes smaller than a target value due to the variation, a short circuit may occur between adjacent word lines. Alternatively, if the line widths of the word lines become smaller than the target value, the word lines may become disconnected. This phenomenon may also occur in groups of the plural bit lines.

### BRIEF DESCRIPTION OF THE DRAWINGS

FIG. 1 is a plan view schematically showing a storage cell array of a nonvolatile memory device according to an embodiment;

FIGS. 2A to 2C are cross-sectional views schematically showing a storage element of the nonvolatile memory device according to the embodiment;

FIG. 3 is a block diagram of the nonvolatile memory device including a storage cell array according to the embodiment;

FIG. 4 is a plan view schematically describing a control method that is a reference example in the nonvolatile memory device according to the embodiment;

FIG. 5 is a diagram showing an I-V curve between a current flowing inside the storage element and a voltage applied to the storage element;

FIG. 6 is a plan view schematically describing a method for controlling the nonvolatile memory device according to the embodiment;

FIG. 7 is a plan view schematically describing another method for controlling the nonvolatile memory device according to the embodiment;

FIG. 8 is a plan view schematically describing still another method for controlling the nonvolatile memory device according to the embodiment; and

FIG. 9 is a plan view schematically describing still another method for controlling the nonvolatile memory device according to the embodiment.

### DETAILED DESCRIPTION

In general, according to one embodiment, a nonvolatile memory device includes: a plurality of word lines extending in a first direction, widths of the word lines in a second direction intersecting the first direction having a first width and a second width greater than the first width; a plurality of bit lines provided above or under the word lines, the bit lines extending in the second direction, widths of the bit lines in the first direction having a third width and a forth width greater than the third width; a plurality of storage elements provided at respective positions where the plurality of word lines and the plurality of bit lines intersect; and a control circuit applying a potential for at least one of a plurality of non-selected word lines and a plurality of non-selected bit lines other than a selected word line and a selected bit line connected to a selected storage element, among the word lines and the bit lines, the potential applied thereto according to a width thereof.

Hereinafter, exemplary embodiments will be described with reference to the accompanying drawings. In the following description, the same reference numerals are given to the same members, and description of components described once may not be repeated.

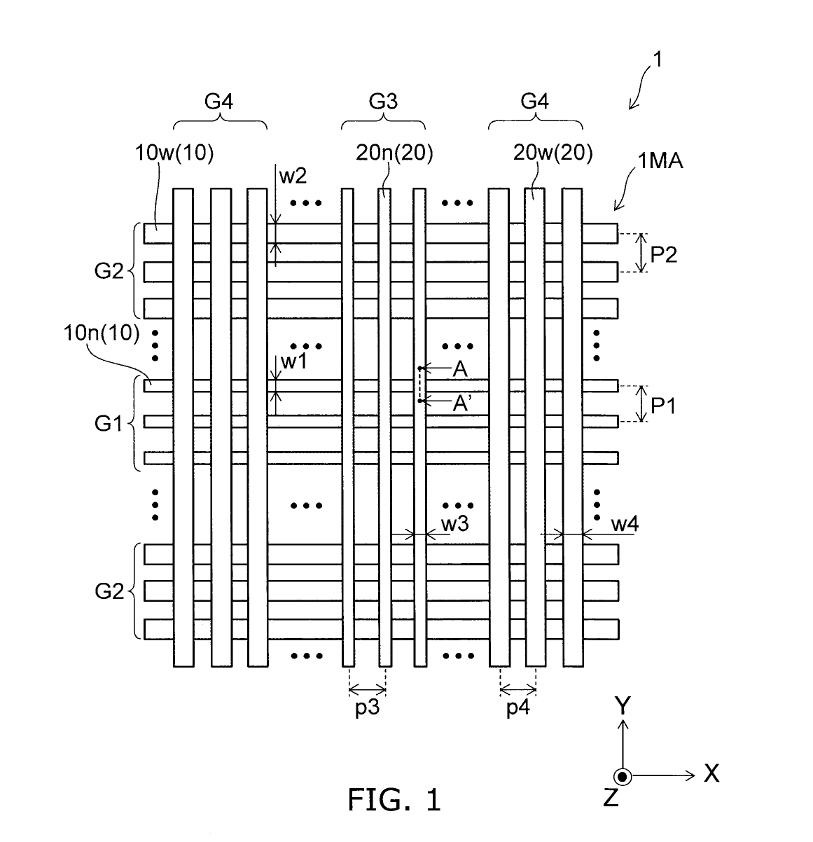

FIG. 1 is a plan view schematically showing a storage cell array of a nonvolatile memory device according to the embodiment.

A nonvolatile memory device 1 is a resistance change-type memory, and includes plural word lines 10, plural bit lines 20, and storage elements in which resistance changes in a storage cell array 1MA. Each storage element is provided in a position where each of the plural word lines 10 and each of the plural bit lines 20 intersect each other (which will be described later).

In the nonvolatile memory device 1, the plural word lines 10 extend in the X-direction (first direction), and are arranged in the Y-direction (second direction) intersecting the X-direction. The plural bit lines 20 are provided above the plural word lines 10, extend in the Y-direction, and are arranged in the X-direction.

In the nonvolatile memory device 1, the plural bit lines 20 may be provided under the plural word lines 10. Alternatively, a group of the plural word lines 10 and a group of the plural bit lines 20 may be alternately arranged in the Z-direction intersecting the X-direction and the Y-direction.

When viewing the nonvolatile memory device 1 from the Z-direction, the plural word lines 10 include a first group G1, and a second group G2 disposed on both sides of the first group G1. In other words, the first group G1 is a group of a central part of the plural word lines 10, and the second group G2 is a group of an end part thereof.

In a word line 10n that belongs to the first group G1, a width (line width) in the Y-direction is formed with a width W1 (first width). In a word line 10w that belongs to the second group G2, a width in the Y-direction is formed with a width W2 (second width). The width W2 is wider than the width W1. Further, in the Y-direction, a pitch P2 of the word lines 10 that belong to the second group G2 is formed to be larger than a pitch P1 of the word lines 10 that belong to the first group G1.

Further, when viewing the nonvolatile memory device 1 from the Z-direction, the plural bit lines 20 include a third group G3, and a fourth group G4 disposed on both sides of the third group G3. In other words, the third group G3 is a group of a central part of the plural bit lines 20, and the fourth group G4 is a group of an end part thereof.

In a bit line 20n that belongs to the third group G3, a width in the X-direction is formed with a width W3 (third width). In a bit line 20w that belongs to the fourth group G4, a width in the X-direction is formed with a width W4 (fourth width). The width W4 is wider than the width W3. Further, in the X-direction, a pitch P4 of the bit lines 20 that belong to the fourth group G4 is formed to be larger than a pitch P3 of the bit lines 20 that belong to the third group G3.

The storage element of the nonvolatile memory device 1 will be described.

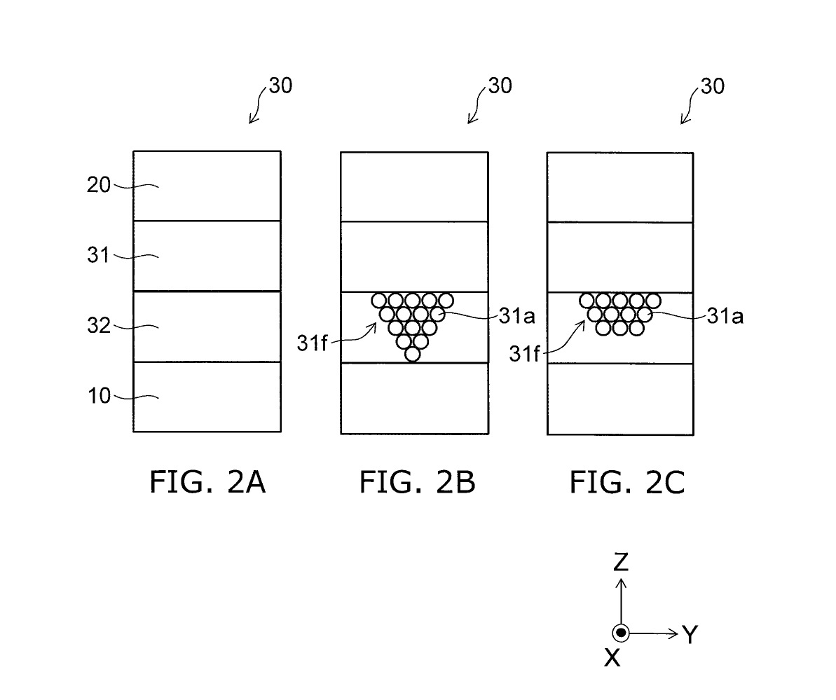

FIGS. 2A to 2C are cross-sectional views schematically showing the storage element of the nonvolatile memory device according to the embodiment.

FIGS. 2A to 2C show an example of a cross section taken along line A-A′ in FIG. 1.

A storage element 30 shown in FIG. 2A represents a state before writing. The storage element 30 is provided at a position where the word line 10 and the bit line 20 intersect each other. The storage element 30 includes a metal ion-source layer 31 and a resistance changing layer 32 between the word line 10 and the bit line 20. For example, the metal ion-source layer 31 is provided on the side of the bit line 20, and the resistance changing layer 32 is provided on the side of the word line 10. The metal ion-source layer 31 may include Ag, Cu, Ni or the like, but in the following description, includes Ag as an example. The resistance changing layer 32 includes silicon (Si), for example. For example, the resistance changing layer 32 may be an oxide silicon layer, a polysilicon layer, a stacked body of the oxide silicon layer and the polysilicon layer, or the like. The resistance changing layer is not limited to the layer including silicon. GST, HfOx, AlOx, or the like may be used as the resistance changing layer. The resistance changing layer 32 comes in contact with the metal ion-source layer 31, and metal ions discharged from the metal ion-source layer 31 are diffused into the resistance changing layer 32.

Then, as shown in FIG. 2B, a predetermined voltage is applied between the word line 10 and the bit line 20. Here, a high potential is applied to the bit line 20 compared with the word line 10. Thus, metal ions (for example, Ag ions) 31a are discharged toward the resistance changing layer 32 from the metal ion-source layer 31, so that a filament 31f including the metal ions 31a is formed.

As the voltage is continuously applied, a lower end of the filament 31f comes in contact with the word line 10. Then, the resistance of the storage element 30 transitions to a low resistance state “1” from a high resistance state “0”, so that data writing is performed in the storage element 30. This operation is referred to as a setting operation. Further, the voltage when the setting operation is performed is referred to as a setting voltage. In addition, a state of the storage element 30 after the setting operation may be referred to as a setting state.

Then, as shown in FIG. 2C, a low potential is applied to the bit line 20 compared with the word line 10 (reverse bias state). Thus, the metal ions (for example, Ag ions) 31a return toward the metal ion-source layer 31 from the resistance changing layer 32, and the lower end of the filament 31f is separated from the word line 10. That is, the filament 31f is not in contact with the word line 10. Thus, the resistance of the storage element 30 transitions to the high resistance state “0” from the low resistance state “1”, and thus, the data written in the storage element 30 is deleted. This operation is referred to as a reset operation. The voltage when the reset operation is performed is referred to as a reset voltage. In addition, a state of the storage element 30 after the reset operation may be referred to as a reset state.

In the nonvolatile memory device 1 according to the embodiment, in the plural word lines 10, the end part thereof (the second group G2) is designed to be wider in line width and longer in pitch than the central part (the first group G1). Accordingly, the processing variation of the line width or the pitch due to the above-mentioned periodicity loss in the end part does not easily occur.

Accordingly, the line width of each of the plural word lines 10 is suppressed from becoming thicker than a target value, or the pitch thereof is suppressed from becoming narrower than a target value. Thus, the short circuit between the adjacent word lines 10 or the disconnection of the word lines 10 does not easily occur. The same effects are achieved in the plural bit lines 20.

Hereinafter, the nonvolatile memory device 1 according to the embodiment will be described.

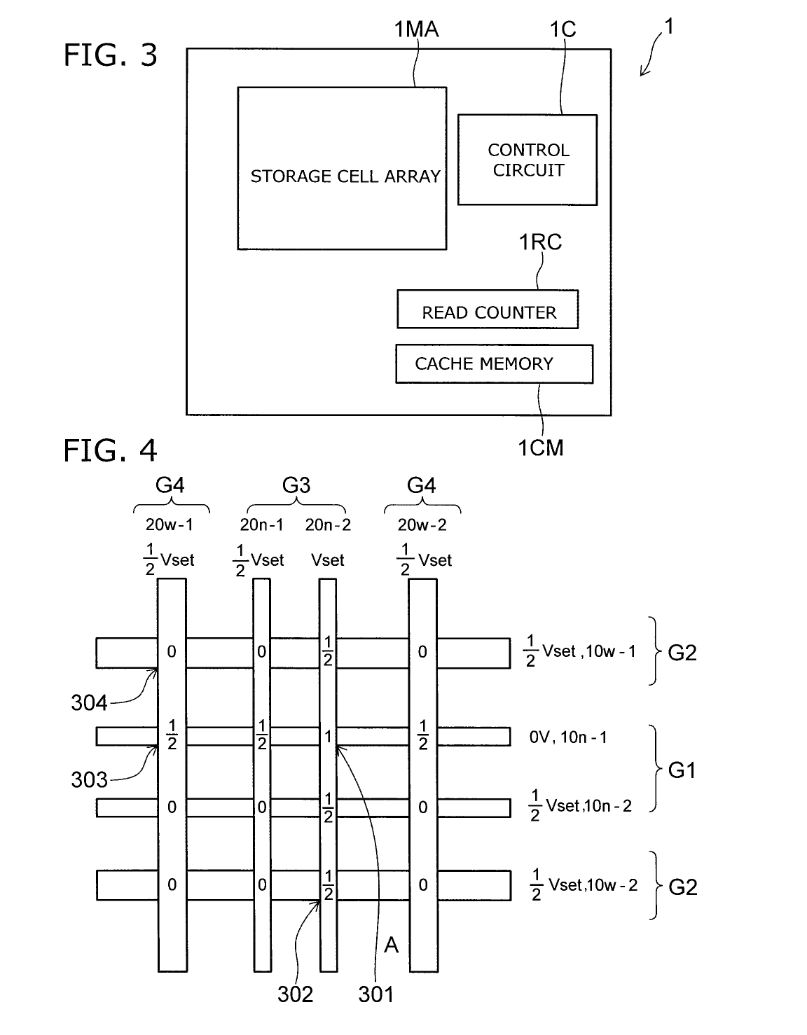

FIG. 3 is a block diagram of the nonvolatile memory device including the storage cell array according to the embodiment.

The nonvolatile memory device 1 includes a control circuit 1C capable of supplying potentials to each of the plural word lines 10 and each of the plural bit lines 20, or detecting the resistance of each storage element 30, in addition to the storage cell array 1MA. Further, the nonvolatile memory device 1 includes a read counter 1RC that counts the number of writings of the storage element 30, a cache memory 1CM, and the like.

Next, a method for controlling (operating) the nonvolatile memory device 1 will be described.

First, a control method that is a reference example in the nonvolatile memory device 1 according to the embodiment will be described.

FIG. 4 is a plan view schematically describing the control method that is the reference example in the nonvolatile memory device according to the embodiment.

In FIG. 4, for example, two word lines 10n-1 and 10n-2 are shown as the word lines 10n that belong to the first group G1, and two word lines 10w-1 and 10w-2 are shown as the word lines 10w that belong to the second group G2.

Further, for example, two bit lines 20n-1 and 20n-2 are shown as the bit lines 20n that belong to the third group G3, and two bit lines 20w-1 and 20w-2 are shown as the bit lines 20w that belong to the fourth group G4.

Here, a storage element 30 disposed between the word line 10n (narrow) that belongs to the first group G1 and the bit line 20n (narrow) that belongs to the third group G3 is represented as a first storage element 301, a storage element 30 disposed between the word line 10w (thick) that belongs to the second group G2 and the bit line 20n (narrow) that belongs to the third group G3 is represented as a second storage element 302, a storage element 30 disposed between the word line 10n (narrow) that belongs to the first group G1 and the bit line 20w (thick) that belongs to the fourth group G4 is represented as a third storage element 303, and a storage element 30 disposed between the word line 10w (thick) that belongs to the second group G2 and the bit line 20w (thick) that belongs to the fourth group G4 is represented as a fourth storage element 304.

For example, when writing data in the first storage element 301 (arrow A) provided between the word line 10n-1 and the bit line 20n-2, the control circuit 1C performs a control so that 0 V is applied to the word line 10n-1, and performs a control so that Vset (V) is applied to the bit line 20n-2. Here, the Vset (V) refers to a voltage at which the setting operation is available. Further, the control circuit 1C performs a control so that (½) Vset (V) that is half the Vset (V) is applied to the word lines 10 and the bit lines 20 other than the word line 10n-1 and the bit line 20n-2.

In FIG. 4, the voltages applied to the respective storage elements are shown as numerical values at positions where the bit lines and the word lines intersect each other. In this figure, “Vset” is omitted from the numerical values. That is, “1” means Vset, and “½” means (½) Vset.

Thus, for example, the setting voltage Vset (V) is selectively applied to the first storage element 301 provided between the word line 10n-1 and the bit line 20n-2, indicated by a reference numeral 301, so that data writing is performed.

In the storage elements 30 other than the first storage element 301 shown by the arrow A, (½) Vset (V) of such a degree that the storage element 30 does not transition to the setting state is applied between the word lines 10 and the bit lines 20.

In this way, the writing is performed only in a specific storage element 30 in the storage cell array 1MA by the control circuit 1C.

Here, when 0 V is applied to the word line 10n-1, Vset (V) is applied to the bit line 20n-2, and (½) Vset (V) is applied to the word lines 10 and the bit lines 20 other than the word line 10n-1 and the bit line 20n-2, (½) Vset (V) is applied to the third storage element 303 provided between the word line 10n-1 and the bit line 20w-1, and between the word line 10n-1 and the bit line 20w-2, by the control circuit 1C.

Here, the width W4 of the bit line 20w is wider than the width W3 of the bit line 20n. Accordingly, even though (½) Vset (V) lower than the setting voltage is applied between the word line 10n-1 and the bit line 20w-1, and between the word line 10n-1 and the bit line 20w-2, as the line widths of the bit lines are wide, a current close to a current value when the writing is performed in the first storage element 301 may flow into the third storage element 303 provided between the word line 10n-1 and the bit line 20w-1, and between the word line 10n-1 and the bit line 20w-2.

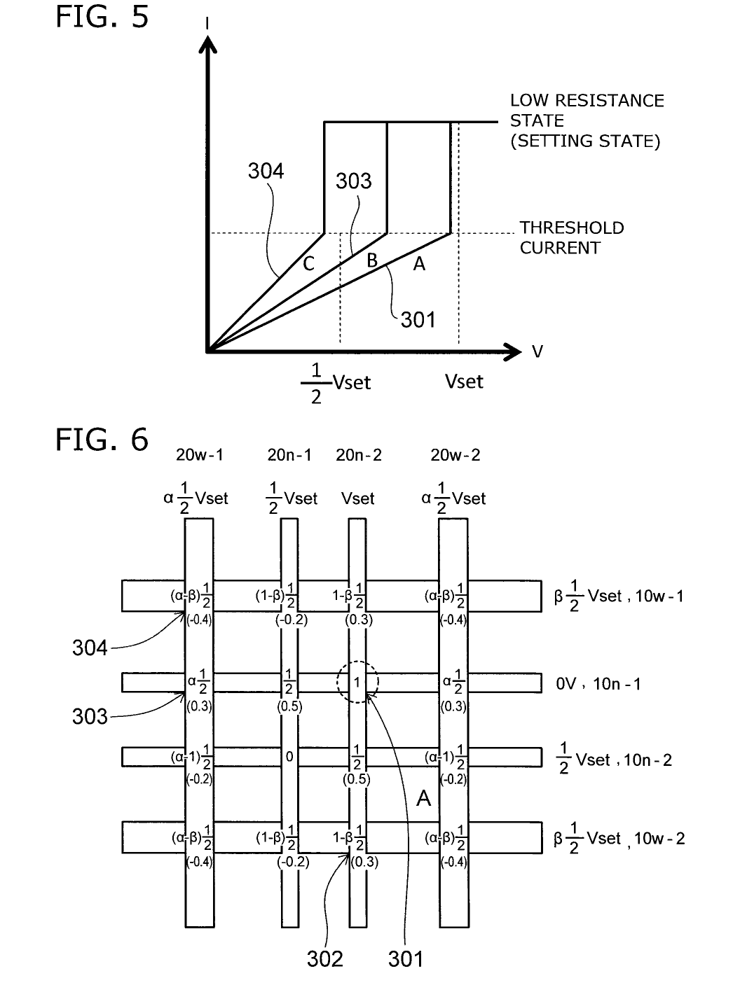

This phenomenon will be described with reference to FIG. 5.

FIG. 5 is a diagram showing an I-V curve between a current flowing inside a storage element and a voltage applied to the storage element.

A curve of line A represents an I-V curve of the first storage element 301 in which the above-mentioned writing is performed. It can be understood that if Vset (V) is applied between the word line 10n-1 and the bit line 20n-2, the resistance of the first storage element 301 becomes equal to or lower than a predetermined threshold resistance (first threshold resistance) from the high resistance state (reset state) to transition to the low resistance state (setting state) in which the resistance is equal to or lower than the threshold resistance, so that the current flowing in the first storage element 301 increases. Here, if the current exceeds a threshold current, the setting state is obtained. That is, the current that flows immediately after the filament 31f comes in contact with the word line 10 is equal to the threshold current, and then, the setting state is performed.

Next, a curve of line B represents an I-V curve of the third storage element 303 provided between the word line 10n-1 and the bit line 20w-1, and between the word line 10n-1 and the bit line 20w-2.

Even though the voltage (for example, (½) Vset (V)) lower than the setting voltage is applied between the word line 10n-1 and the bit line 20w-1, and between the word line 10n-1 and the bit line 20w-2, as the line widths of the bit lines 20w-1 and 20w-2 are wide, a current close to the threshold current may substantially flow. Thus, if (½) Vset (V) is continuously applied, the third storage element 303 (FIG. 4) provided between the word line 10n-1 and the bit line 20w-1, and between the word line 10n-1 and the bit line 20w-2 may transition to the setting state. That is, the data writing may mistakenly occur. Further, the other storage elements provided between the word lines 10w and the bit lines 20n, and between the word lines 10n and the bit lines 20w, in addition to the third storage element 303, may transition to the setting state.

Further, a curve of line C represents an I-V curve of the fourth storage element 304. In this case, since the word line and the bit line are the word line 10w and the bit line 20w having the same wide width, the I-V curve transitions to the low resistance state (setting state) from the high resistance state (reset state) at a voltage lower than those of lines A and B. In other words, if the voltage that is lower than (½) Vset (V) is continuously applied, the fourth storage element 304 may transition to the setting state.

In order to reliably prevent this transition, the control circuit 1C performs a control as described below.

The control circuit 1C selects a (writing) storage element that is to transition from the reset state to the setting state among the plural storage elements 30, and then, performs the setting operation of allowing the selected storage element 30 to transition to the setting state from the reset state.

In the setting operation, a potential for giving a predetermined setting voltage to the selected storage element is applied to a selected word line and a selected bit line connected to the selected storage element. For example, Vset (V) is applied to the selected bit line, and 0 (V) is applied to the selected word line.

On the other hand, with respect to a non-selected word line and a non-selected bit line that are not connected to the selected storage element, the applied potential is controlled according to their line widths. Specifically, with respect to at least one of the non-selected word line and the non-selected bit line, the applied potential is controlled according to the line width so that the voltage applied to the non-selected storage element connected to any one of the word line and the bit line that has the relatively wide line width, among the non-selected word line and the non-selected bit line, becomes a voltage that is lower than (½) Vset (V) and prevents the occurrence of the mistaken setting state.

For example, under the above-mentioned condition, the control is performed so that a maximum value of the voltages applied to the non-selected storage element connected to any one of the word line 10w of the second group G2 and the bit line 20w of the fourth group G4, among the voltages applied to the non-selected storage element connected to any one of the non-selected word line and the non-selected bit line, is equal to or lower than a maximum value of the voltages applied to the non-selected storage element connected to an intersecting part of the word line 10n of the first group G1 and the bit line 20n of the third group G3.

In other words, with respect to at least one of the non-selected word line and the non-selected bit line, the applied potential is controlled according to the line widths so that the maximum value of the voltages applied to the non-selected storage element connected to any one of the non-selected word line and the non-selected bit line that has the relatively wide line width is equal to or lower than the maximum value of the voltages applied to the non-selected storage element connected to the intersecting part of the non-selected word line and the non-selected bit line that have the relatively narrow line width.

For example, in the word line 10 that is not connected to the selected storage element, the control circuit 1C performs the control for changing the potential applied to the word line 10n of the first group G1 and the potential applied to the word line 10w of the second group G2 according to the respective widths. Further, in the bit line 20 that is not connected to the selected storage element, the control circuit 1C performs the control for changing the potential applied to the bit line 20n of the third group G3 and the potential applied to the bit line 20w of the fourth group G4 according to the respective widths.

This is because if the same potential ((½) Vset) is applied to the bit line 20n and the bit line 20w that are not connected to the selected storage element 30, as described above, the storage element 30 or the like may transition to the setting state. In order to avoid this transition, the control circuit 1C supplies a low potential to the bit line 20w that is not connected to the selected storage element 30, compared with the bit line 20n that is not connected to the selected storage element 30.

Further, in the plural word lines 10 and the plural bit lines 20 that are not connected to the selected storage element 30, the control circuit 1C performs a control so that the maximum value of the voltages applied between the word line 10n of the first group G1 and the bit line 20w of the fourth group G4, and between the word line 10w of the second group G2 and the bit line 20n of the third group G3 becomes lower than the maximum value of the voltages applied between the word line 10n of the first group G1 and the bit line 20n of the third group G3.

Furthermore, in the plural word lines 10 and the plural bit lines 20 that are not connected to the selected storage element 30, the control circuit 1C performs a control so that the maximum value of the voltages applied between the word line 10w of the second group G2 and the bit line 20w of the fourth group G4 is lower than the maximum value of the voltages applied between the word line 10n of the first group G1 and the bit line 20w of the fourth group G4, and between the word line 10w of the second group G2 and the bit line 20n of the third group G3.

Hereinafter, a specific example of the method for suppressing the mistaken writing operation of the nonvolatile memory device 1 will be described with reference to FIGS. 6 to 9, in which the potentials applied to the selected word line, the selected bit line, the non-selected word line, and the non-selected bit line are represented using specific numerical values.

In the embodiment, the voltage applied to the first storage element 301 when the selected first storage element 301 transitions from the reset state to the setting state is referred to as a first voltage (Vset1), the voltage applied to the second storage element 302 and the third storage element 303 when each of the selected second storage element 302 and the selected third storage element 303 transitions from the reset state to the setting state is referred to as a second voltage (Vset2), and the voltage applied to the fourth storage element 304 when the selected fourth storage element 304 transitions from the reset state to the setting state is referred to as a third voltage (Vset3).

The control circuit 1C changes the first to third voltages according to the combinations of the widths of the word lines 10 and the widths of the bit lines 20 connected to the respective first to fourth storage elements to perform the setting operation.

For example, between the first voltage and the second voltage, there is a relationship of “Vset2=k·Vset1” (k: factor (k<0.5)).

When allowing any one of the first to fourth storage elements to transition to the setting state from the reset state, the control circuit 1C performs a control so that the first voltage is higher than the second voltage, and the second voltage is higher than the third voltage.

FIG. 6 is a plan view schematically describing a method for controlling the nonvolatile memory device according to the embodiment.

FIG. 6 shows an example of an operation when the writing is selectively performed in the first storage element 301 provided between the narrow word line 10n-1 and the narrow bit line 20n-2.

When allowing the selected first storage element 301 to transition to the setting state from the reset state, the control circuit 1C applies a ground potential (first potential) to the word line connected to the first storage element 301, and applies a Vset potential (second potential) at which the first storage element 301 transitions to the setting state from the reset state, to the bit line connected to the first storage element 301.

Further, a (½)·Vset potential (third potential) is applied to the word line of the first group G1 that is not connected to the selected first storage element 301. Here, the (½)·Vset potential (third potential) is larger than the ground potential and is smaller than the setting potential. In addition, (½)·Vset is applied to the bit line of the third group G3 that is not connected to the selected first storage element 301.

Further, a potential different from that of the word line of the first group G1 that is not connected to the selected first storage element 301 is applied to the word line of the second group G2 that is not connected to the selected first storage element 301. In addition, a potential different from that of the bit line of the third group G3 that is not connected to the selected first storage element 301 is applied to the bit line of the fourth group G4 that is not connected to the selected first storage element 301.

For example, a potential obtained by multiplying the (½)·Vset potential by a factor α (0.5<α<1.0) is applied to the bit line of the fourth group G4 that is not connected to the selected first storage element 301. Further, a potential obtained by multiplying the (½)·Vset potential by a factor β (1.0<β<1.5) is applied to the word line of the second group G2 that is not connected to the selected first storage element 301.

For example, 0 V is applied to the word line 10n-1, (½)·Vset is applied to the word line 10n-2, Vset is applied to the bit line 20n-2, and (½)·Vset is applied to the bit line 20n-1. Further, α·(½)·Vset obtained by multiplying the (½)·Vset by the factor α (0.5<α<1) is applied to the thick bit lines 20w-1 and 20w-2, and β·(½)·Vset obtained by multiplying the (½)·Vset by the factor β (1<β<1.5) is applied to the thick word lines 10w-1 and 10w-2.

FIG. 6 shows that the voltages applied to the respective storage elements are indicated by expressions (numerical values). As described above, “Vset” is omitted from the expressions (numerical values).

That is, numerical value “1”, that is, “Vset” is applied to the first storage element 301 provided between the word line 10n-1 and the bit line 20n-2. Thus, the first storage element 301 transitions to the setting state from the reset state. Further, among the storage elements provided between the narrow word line 10n and the narrow bit line 20n, a voltage lower than the “Vset” is applied to the storage elements other than the first storage element 301. Thus, the storage elements do not transition to the setting state from the reset state.

On the other hand, voltages indicated as “α·(½)”, “(α−1)·(½)”, “(1-β)·(½)”, and “1−β·(½)” are applied to the storage elements provided between the thick word line 10w and the narrow bit line 20n, and between the narrow word line 10n and the thick bit line 20w (in which “Vset” is similarly omitted).

Here, when α=0.6 and β=1.4, “a·(½)”, “(α−1)·(½)”, “(1−β)·(½)”, and “1−β·(½)” become “0.3”, “−0.2”, “−0.2”, and “0.3”, respectively, and the values become smaller than “0.5”. For example, 0.3 Vset is applied to the second storage element 302, and 0.3 Vset is applied to the third storage element 303. The negative value means the reset operation, in which the storage element does not transition to the setting operation.

Here, the maximum value of the voltages applied to the second storage element 302 or the third storage element 303 is “0.3”, which is lower than the maximum value “0.5” applied to the non-selected first storage element 301.

Thus, the storage element provided between the thick word line 10w and the narrow bit line 20n, and the storage element provided between the narrow word line 10n and the thick bit line 20w do not transition to the setting state from the reset state.

Further, a voltage of a value of “(α−β) (½)” is applied to the storage element provided between the thick word line 10w and the thick bit line 20w. Here, when α=0.6 and β=1.4, “(α−β)(½)” becomes “−0.4”. For example, −0.4 Vset is applied to the fourth storage element 304. That is, the negative voltage is applied to the storage element provided between the thick word line 10w and the thick bit line 20w, which maintains the reset state.

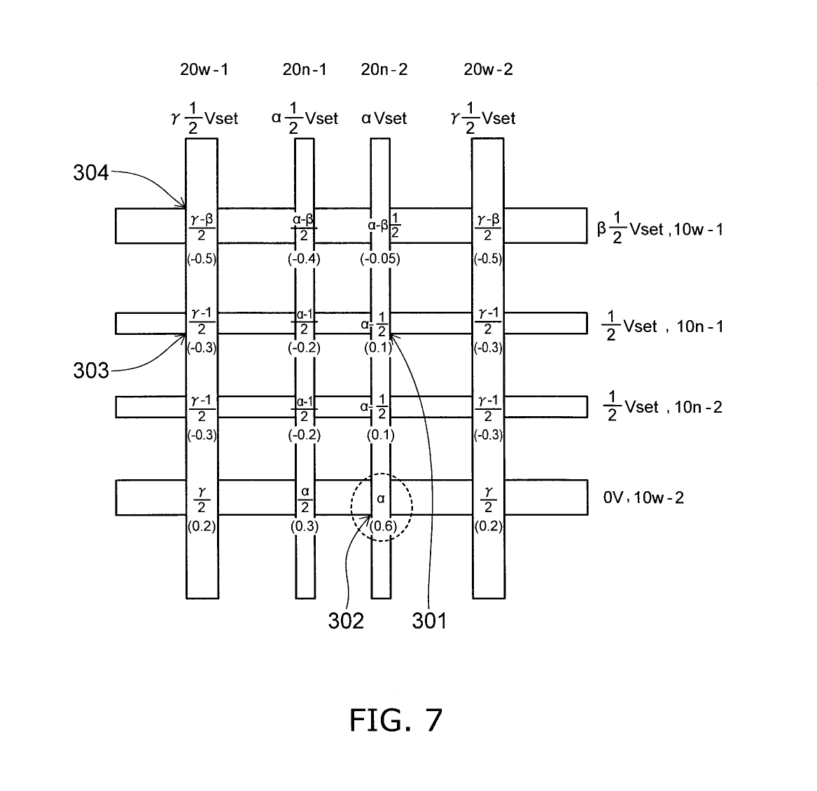

FIG. 7 is a plan view schematically describing another method for controlling the nonvolatile memory device according to the embodiment.

FIG. 7 shows an example of an operation when the writing is selectively performed in the second storage element 302 provided between the thick word line 10w-2 and the narrow bit line 20n-2.

When allowing the selected second storage element 302 to transition to the setting state from the reset state, the control circuit 1C applies the ground potential to the word line connected to the second storage element 302, and applies the potential obtained by multiplying the Vset potential by the factor α to the bit line connected to the second storage element 302. As described above, if a voltage lower than Vset, that is, α·Vset is applied, the second storage element 302 transitions to the setting state from the reset state.

Further, the potential obtained by multiplying the (½)·Vset potential by the factor β is applied to the word lines of the second group G2 that are not connected to the selected second storage element 302. Further, the potential obtained by multiplying the (½)·Vset potential by the factor α is applied to the bit lines of the third group G3 that are not connected to the selected second storage element 302.

In addition, the (½)·Vset potential is applied to the word lines of the first group G1. Further, the potential obtained by multiplying the (½)·Vset potential by a factor γ (0.1<γ<0.5) is applied to the bit lines of the fourth group G4. In the example of FIG. 7, the word lines of the first group G1 and the bit lines of the fourth group G4 are not connected to the selected second storage element 302.

For example, (½)·Vset is applied to the word lines 10n-1 and 10n-2. α·(½)·Vset obtained by multiplying the (½)·Vset by the factor α (0.5<α<1) is applied to the bit line 20n-1. α·Vset obtained by multiplying the Vset by the factor α is applied to the bit line 20n-2.

Further, γ·(½)·Vset obtained by multiplying (½)·Vset by the factor γ (0.1<γ<0.5) is applied to the bit lines 20w-1 and 20w-2. Further, β·(½)·Vset obtained by multiplying (½)·Vset by the factor β(1<β<1.5) is applied to the word line 10w-1.

FIG. 7 shows that the voltages applied to the respective storage elements are indicated by expressions (numerical values). As described above, “Vset” is omitted from the expressions (numerical values).

That is, the numerical value “α”, that is, “α·Vset” is applied to the second storage element 302 provided between the word line 10w-2 and the bit line 20n-2, and thus, the second storage element 302 transitions to the setting state from the reset state.

Further, the voltage (0.1 V or lower, for example) lower than “Vset” is applied to the storage elements provided between the narrow word lines 10n and the narrow bit lines 20n, and thus, the storage elements do not transition to the setting state from the reset state.

On the other hand, the voltages indicated as “(γ−1)/2”, “(α−β)/2”, and “α/2” are applied to the storage elements other than the second storage element 302, among the storage elements provided between the thick word lines 10w and the narrow bit lines 20n and the storage elements provided between the narrow word lines 10n and the thick bit lines 20w (in which “Vset” is similarly omitted).

Here, when α=0.6, β=1.4, and γ=0.4, “(γ−1)/2”, “(α−β)/2”, and “α/2” become “−0.3”, “−0.4”, and “0.3”, respectively, and the values become smaller than “0.5”. That is, the storage elements other than the second storage element 302 among the storage elements provided between the thick word lines 10w and the narrow bit lines 20n and the storage elements provided between the narrow word lines 10n and the thick bit lines 20w do not transition to the setting state. The negative value means that the reset operation is performed in the storage element.

Further, voltages of values of “(γ−β)/2” and “γ/2” are applied to the storage element provided between the thick word line 10w and the thick bit line 20w. Here, when β=1.4, “(γ−β)/2” and “γ/2” become “−0.5” and “0.2”. That is, the storage element provided between the thick word line 10w and the thick bit line 20w does not transition to the setting state.

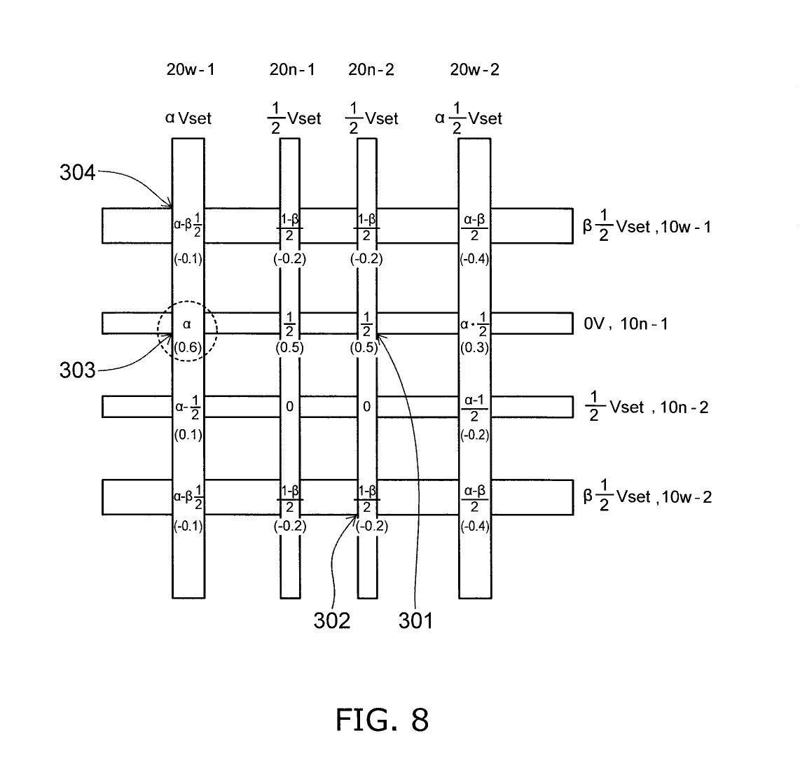

FIG. 8 is a plan view schematically describing still another method for controlling the nonvolatile memory device according to the embodiment.

FIG. 8 shows an example of an operation when the writing is selectively performed in the third storage element 303 provided between the narrow word line 10n-1 and the thick bit line 20w-1.

When allowing the selected third storage element 303 to transition to the setting state from the reset state, the control circuit 1C applies the ground potential to the word line connected to the third storage element 303, and applies the potential obtained by multiplying the Vset potential by the factor α to the bit line connected to the third storage element 303.

Further, the (½)·Vset potential is applied to the word line of the first group G1 that is not connected to the selected third storage element 303, and the potential obtained by multiplying the (½)·Vset potential by the factor α is applied to the bit line of the fourth group G4 that is not connected to the selected third storage element 303.

In addition, the (½)·Vset potential is applied to the bit line of the third group G3. Further, the potential obtained by multiplying the (½)·Vset potential by the factor 13 is applied to the word line of the second group G2. In the example of FIG. 8, the bit line of the third group G3 and the word line of the second group G2 are not connected to the selected third storage element 303.

For example, 0 V is applied to the word line 10n-1, (½)·Vset is applied to the word line 10n-2, and the (½)·Vset is applied to the bit lines 20n-1 and 20n-2.

Further, β·(½)·Vset obtained by multiplying by the factor β (1<β<1.5) is applied to the word lines 10w-1 and 10w-2. Further, α·Vset obtained by multiplying Vset by the factor α (0.5<α<1) is applied to the bit line 20w-1, and α·(½)·Vset obtained by multiplying (½)·Vset by the factor α is applied to the bit line 20w-2.

FIG. 8 shows that the voltages applied to the respective storage elements are indicated by expressions (numerical values). As described above, “Vset” is omitted from the expressions (numerical values).

That is, the numerical value “α”, that is, “α·Vset” is applied to the third storage element 303 provided between the word line 10n-1 and the bit line 20w-1, and thus, the third storage element 303 transitions to the setting state from the reset state.

Further, the voltage (0.5 V or lower, for example) lower than “Vset” is applied to the storage elements provided between the narrow word lines 10n and the narrow bit lines 20n, and thus, the storage elements do not transition to the setting state from the reset state.

On the other hand, the voltages indicated as “α−½”, “(1−β)/2”, “α·(½)”, and “(α−1)/2” are applied to the storage elements other than the third storage element 303, among the storage elements provided between the thick word lines 10w and the narrow bit lines 20n and the storage elements provided between the narrow word lines 10n and the thick bit lines 20w (in which “Vset” is similarly omitted).

Here, when α=0.6 and β=1.4, “α−½”, “(1-β)/2”, “α·(½)”, and “(α−1)/2” become “0.1”, “−0.2”, “0.3”, and “−0.2”, respectively, and the values become smaller than “0.5”. That is, the storage elements other than the third storage element 303 among the storage elements provided between the thick word lines 10w and the narrow bit lines 20n and the storage elements provided between the narrow word lines 10n and the thick bit lines 20w do not transition to the setting state.

Further, voltages of values of “α−β·(½)” and “(α−β)/2” are applied to the storage element provided between the thick word lines 10w and the thick bit lines 20w. Here, when α=0.6 and β=1.4, “(α−β)(½)” becomes “−0.1”, and “(α−β)/2” becomes “−0.4”. That is, the negative voltage is applied to the storage element provided between the thick word lines 10w and the thick bit lines 20w to maintain the reset state.

In this way, in FIGS. 7 and 8, the control is performed so that the maximum value (0.2 in FIG. 7 and −0.1 in FIG. 8) of the voltages applied between the word lines 10w of the second group G2 and the bit lines 20w of the fourth group G4 is lower than the maximum value (0.3 in FIG. 7 and 0.3 in FIG. 8) of the voltages applied between the word lines 10n of the first group G1 and the bit lines 20w of the fourth group G4, and between the word lines 10w of the second group G2 and the bit lines 20n of the third group G3.

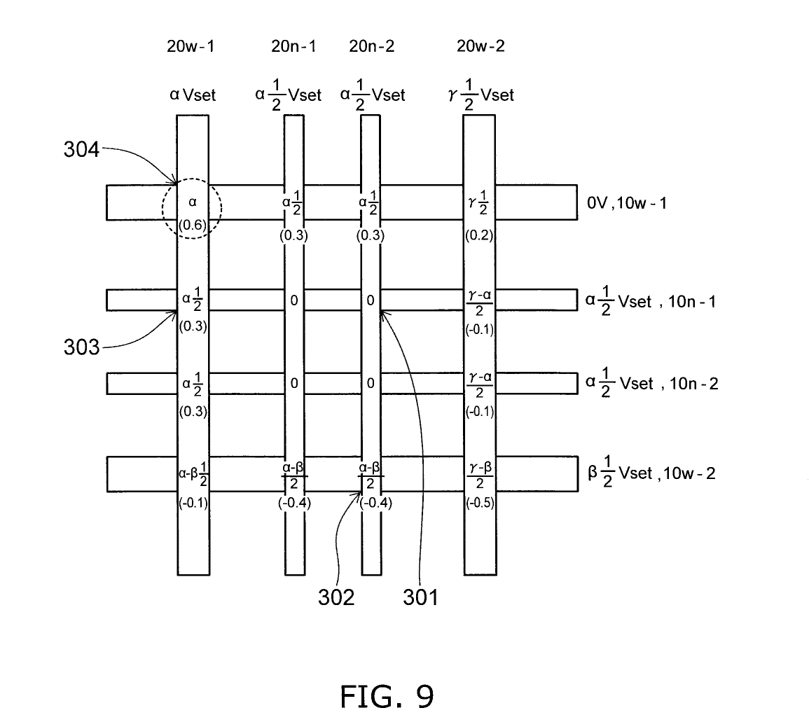

FIG. 9 is a plan view schematically describing still another method for controlling the nonvolatile memory device according to the embodiment.

FIG. 9 shows an example of an operation when the writing is selectively performed in the fourth storage element 304 provided between the thick word line 10w-1 and the thick bit line 20w-1.

When allowing the selected fourth storage element 304 to transition to the setting state from the reset state, the control circuit 1C applies the ground potential to the word line connected to the fourth storage element 304, and applies the potential obtained by multiplying the Vset potential by the factor α to the bit line connected to the fourth storage element 304.

Further, the potential obtained by multiplying the (½)·Vset potential by the factor 13 is applied to the word lines of the second group G2 that are not connected to the selected fourth storage element 304, and the potential obtained by multiplying the (½)·Vset potential by the factor γ (0.1<γ<0.5) is applied to the bit lines of the fourth group G4 that are not connected to the fourth storage element.

In addition, the potential obtained by multiplying the (½)·Vset potential by the factor α is applied to the bit lines of the third group G3. Further, the potential obtained by multiplying the (½)·Vset potential by the factor α is applied to the word lines of the first group G1. In the example of FIG. 9, the bit lines of the third group G3 and the word lines of the first group G1 are not connected to the selected fourth storage element 304.

For example, α·(½)·Vset is applied to the word lines 10n-1 and 10n-2, and α·(½)·Vset is applied to the bit lines 20n-1 and 20n-2.

Further, 0 V is applied to the word line 10w-1, and β·(½)·Vset obtained by multiplying (½)·Vset by the factor β (1<β<1.5) is applied to the word line 10w-2. In addition, α·Vset obtained by multiplying Vset by the factor α (0.5<α<1) is applied to the bit line 20w-1, and γ·(½)·Vset obtained by multiplying (½)·Vset by the factor γ (0.1<γ<0.5) is applied to the bit line 20w-2.

FIG. 9 shows that the voltages applied to the respective storage elements are indicated by expressions (numerical values). As described above, “Vset” is omitted from the expressions (numerical values).

That is, the numerical value “α”, that is, “α·Vset” is applied to the fourth storage element 304 provided between the word line 10w-1 and the bit line 20w-1, and thus, the fourth storage element 304 transitions to the setting state from the reset state. Further, voltages lower than “Vset” are applied (for example, 0 V) to the storage elements provided between the narrow word lines 10n and the narrow bit lines 20n, and thus, the storage elements do not transition to the setting state from the reset state.

On the other hand, the voltages indicated as “α·(½)”, “(α−β)/2”, and “(γ−α)/2” are applied to the storage elements provided between the thick word lines 10w and the narrow bit lines 20n, and the storage elements provided between the narrow word lines 10n and the thick bit lines 20w (in which “Vset” is similarly omitted).

Here, when α=0.6, β=1.4, and γ=0.4, “α·(½)”, “(α−β)/2”, and “(γ−α)/2” become “0.3”, “−0.4”, and “−0.1”, respectively, and the values become smaller than “0.25”. That is, the storage elements provided between the thick word lines 10w and the narrow bit lines 20n, and the storage elements provided between the narrow word lines 10n and the thick bit lines 20w do not transition to the setting state.

Further, voltages of values of “α−β·(½)”, “α·(½)”, and “(γ−β)/2” are applied to the storage elements other than the fourth storage element 304, among the storage elements provided between the thick word lines 10w and the thick bit lines 20w. Here, when α=0.6, β=1.4, and γ=0.4, “α−β·(½)”, “α·(½)”, and “(γ−β)/2” become “−0.1”, “0.2”, and “−0.5”, which are smaller than 0.25. That is, the storage elements provided between the thick word lines 10w and the thick bit lines 20w, other than the fourth storage element 304, do not transition to the setting state.

According to such a control, the mistaken writing operation is suppressed.

Further, when the resistance of the second storage element 302 or the resistance of the third storage element 303 becomes lower than the second threshold resistance according to the application of the first voltage to the first storage element 301 plural times, the control circuit 1C may apply the reset voltage for returning the resistance of the second storage element 302 or the resistance of the third storage element 303 to the reset state to the second storage element 302 or the third storage element 303. The second threshold resistance may be the same as the above-mentioned first threshold resistance.

That is, when the resistance of the second storage element 302 or the resistance of the third storage element 303 is lower than the second threshold resistance by repeating the setting operation of the first storage element 301, the control circuit 1C may consider that the second storage element 302 or the third storage element 303 is in the setting state, and may return the second storage element 302 or the third storage element 303 to the reset state. According to such a control, similarly, the mistaken data writing operation is suppressed.

Further, when the number of applications of the first voltage to the first storage element 301 reaches a threshold value, the control circuit 1C may apply the reset voltage for returning the resistance of the second storage element 302 or the resistance of the third storage element 303 to the reset state to the second storage element 302 or the third storage element 303.

That is, the read counter 1RC counts the number of data writings for the first storage element 301, and if it is determined by the control circuit 1C that the number of writings has reached the threshold value, the control circuit 1C may consider that the second storage element 302 or the third storage element 303 is in the setting state, and may return the second storage element 302 or the third storage element 303 to the reset state. According to such a control, similarly, the mistaken data writing operation is suppressed.

Further, when the number of applications of the first voltage to the first storage element 301 reaches the threshold value, the control circuit 1C may apply the reset voltage for returning the resistance of the first storage element 301, the resistance of the second storage element 302, the resistance of the third storage element 303, and the resistance of the fourth storage element 304 to the reset state to the first storage element 301, the second storage element 302, the third storage element 303, and the fourth storage element 304.

That is, the read counter 1RC counts the number of data writings for the first storage element 301, and if it is determined by the control circuit 1C that the number of data writings is the threshold value, the control circuit 1C may return all the storage elements 30 to the reset state. According to such a control, similarly, the mistaken data writing operation is suppressed. Data before being reset, stored in the first storage element 301, is stored in the cache memory 1CM by the control circuit 1C.

Further, the control circuit 1C may change the frequency of the reset operation for returning the resistance of the first storage element 301, the resistance of the second storage element 302, the resistance of the third storage element 303, and the resistance of the fourth storage element 304 to the reset state according to a combination of the widths of the word lines 10 and the widths of the bit lines 20 respectively connected to the first to fourth storage elements. For example, the probability of the mistaken operation is higher in a combination of the narrower width of the word line 10 and the narrower width of the bit line 20. Accordingly, the frequency of the reset operation is set to be higher in the combination of the narrower width of the word line 10 and the narrower width of the bit line 20.

Further, the control circuit 1C may apply the reset voltage for periodically returning any one resistance of the second storage element 302, the third storage element 303, and the fourth storage element 304 provided in the end part of the storage cell array to the reset state to any one of the second storage element 302, the third storage element 303, and the fourth storage element 304.

For example, when the second storage element 302, the third storage element 303, and the fourth storage element 304 provided in the end part are not actually used as the storage element, the storage elements may mistakenly operate to transition to the setting state from the reset state. For example, when the fourth storage element 304 is not actually used as the storage element, if the fourth storage element 304 mistakenly operates, the word line 10 and the bit line 20 connected to the fourth storage element 304 are short-circuited. Accordingly, the writing and the deletion cannot be performed for the other storage elements connected to the word line 10 and the bit line 20 connected to the fourth storage element 304. In order to prevent this problem, the above-described control is performed.

The embodiments have been described above with reference to examples. However, the embodiments are not limited to these examples. More specifically, these examples can be appropriately modified in design by those skilled in the art. Such modifications are also encompassed within the scope of the embodiments as long as they include the features of the embodiments. The components included in the above examples and the layout, material, condition, shape, size and the like thereof are not limited to those illustrated, but can be appropriately modified.

Furthermore, the components included in the above embodiments can be combined as long as technically feasible. Such combinations are also encompassed within the scope of the embodiments as long as they include the features of the embodiments. In addition, those skilled in the art could conceive various modifications and variations within the spirit of the embodiments. It is understood that such modifications and variations are also encompassed within the scope of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A nonvolatile memory device comprising:
a plurality of word lines extending in a first direction, widths of the word lines in a second direction intersecting the first direction having a first width and a second width greater than the first width;
a plurality of bit lines provided above or under the word lines, the bit lines extending in the second direction, widths of the bit lines in the first direction having a third width and a forth width greater than the third width;
a plurality of storage elements provided at respective positions where the plurality of word lines and the plurality of bit lines intersect; and
a control circuit applying a potential for at least one of a plurality of non-selected word lines and a plurality of non-selected bit lines other than a selected word line and a selected bit line connected to a selected storage element, among the word lines and the bit lines, the potential applied thereto according to a width thereof.

2. The device according to claim 1, wherein
the word lines are arranged in the second direction, width of a first group of the word lines is the first width, width of a second group of the word lines is the second width, and the second group is arranged on both sides of the first group;
the bit lines are arranged in the first direction, width of a third group of the bit lines is the third width, width of a fourth group of the bit lines is the fourth width, and the fourth group is arranged on both sides of the third group.

3. The device according to claim 1, wherein
the storage element includes
a metal ion-source layer; and
a resistance changing layer being in contact with the metal ion-source layer, and capable of diffusion of metal ions discharged from the metal ion-source layer within the resistance changing layer.

4. The device according to claim 2, wherein
the control circuit changes a potential applied to the first group and a potential applied to the second group according to the line widths of the word lines, and changes a potential applied to the third group and a potential applied to the fourth group according to the line widths of the bit lines for the word lines not being connected to the selected storage element and the bit lines not being connected to the selected storage element.

5. The device according to claim 4, wherein
a maximum value of voltages applied between the first group and the fourth group and between the second group and the third group is lower than a maximum value of voltages applied between the first group and the third group in the word lines not being connected to the selected storage element and the bit lines not being connected to the selected storage element.

6. The device according to claim 4, wherein
a maximum value of voltages applied between the second group and the fourth group is lower than a maximum value of voltages applied between the first group and the fourth group and between the second group and the third group in the word lines not being connected to the selected storage element and the bit lines not being connected to the selected storage element.

7. The device according to claim 4, wherein,
in a relationship of
a first voltage applied to a first storage element selected from the storage elements disposed between the first group and the third group,
a second voltage applied to a second storage element selected from the storage elements disposed between the second group and the third group, or a third storage element selected from the storage elements disposed between the first group and the fourth group, and
a third voltage applied to a fourth storage element selected from the storage elements disposed between the second group and the fourth group,
the control circuit performs a control so that the first voltage is higher than the second voltage, and the second voltage is higher than the third voltage when performing setting operation.

8. The device according to claim 7, wherein,
when the selected first storage element transitions to setting state from reset state, the control circuit
applies a first potential to the word line connected to the selected first storage element, and applies a second potential at which the selected first storage element transitions to the setting state from the reset state to the bit line connected to the selected first storage element,
applies a third potential being larger than the first potential and being smaller than the second potential to the word lines of the first group not being connected to the selected first storage element,
applies the third potential to the bit line of the third group not being connected to the selected first storage element,
applies a potential obtained by multiplying the third potential by a factor α (0.5<α<1.0) to the bit lines of the fourth group, and
applies a potential obtained by multiplying the third potential by a factor β (1.0<β<1.5) to the word lines of the second group.

9. The device according to claim 7, wherein
the control circuit is capable of applying a reset voltage for returning the resistance of the second storage element or the resistance of the third storage element to reset state to the second storage element or the third storage element when a resistance of the second storage element or a resistance of the third storage element is lower than a threshold resistance according to the application of plural times of the first voltage to the first storage element.

10. The device according to claim 7, wherein
the control circuit is capable of applying a reset voltage for returning a resistance of the second storage element or a resistance of the third storage element to reset state to the second storage element or the third storage element when a number of applications of the first voltage to the first storage element reaches a threshold value.

11. The device according to claim 7, wherein
the control circuit is capable of applying a reset voltage for returning a resistance of the first storage element, a resistance of the second storage element, a resistance of the third storage element, or a resistance of the fourth storage element to reset state to the first storage element, the second storage element, the third storage element, and the fourth storage element when a number of applications of the first voltage to the first storage element reaches a threshold value.

12. The device according to claim 7, wherein
the control circuit is capable of changing the frequency of a reset operation for returning a resistance of the first storage element, a resistance of the second storage element, a resistance of the third storage element, and a resistance of the fourth storage element to reset state according to combinations of the line widths of the word lines and the line widths of the bit lines connected to the respective first to fourth storage elements.

13. The device according to claim 4, wherein
the control circuit is capable of applying a reset voltage for periodically returning any one resistance of the second storage element, the third storage element, and the fourth storage element to reset state to any one of the second storage element, the third storage element, and the fourth storage element.

14. The device according to claim 2, wherein
the pitch of the word lines belonging to the second group is larger than the pitch of the word lines belonging to the first group in the second direction.

15. The device according to claim 2, wherein
the pitch of the bit lines belonging to the fourth group is larger than the pitch of the bit lines belonging to the third group in the first direction.

16. A nonvolatile memory device comprising:
a plurality of word lines extending in a first direction, the word lines being arranged in a second direction intersecting the first direction, and the word lines including a first group and a second group, width of the first group in the second direction being a first width, width of the second group in the second direction being a second width greater than the first width, and the second group being arranged on both sides of the first group;
a plurality of bit lines provided above or under the plurality of word lines, the bit lines extending in the second direction, the bit lines being arranged in the first direction, the bit lines including a third group and a forth group, width of the third group in the first direction being a third width, width of the fourth group in the first direction being a fourth width greater than the third width, and the fourth group being arranged on both sides of the third group; and
a plurality of storage elements provided at respective positions where the plurality of word lines and the plurality of bit lines intersect.

17. The device according to claim 16, wherein
the storage element includes
a metal ion-source layer; and
a resistance changing layer being in contact with the metal ion-source layer, and capable of diffusion of metal ions discharged from the metal ion-source layer within the resistance changing layer.

18. A method for controlling a nonvolatile memory device including a plurality of word lines extending in a first direction, widths of the word lines in a second direction intersecting the first direction having a first width and a second width greater than the first width, a plurality of bit lines provided above or under the word lines, the bit lines extending in the second direction, widths of the bit lines in the first direction having a third width and a forth width greater than the third width, and a plurality of storage elements provided at respective positions where the plurality of word lines and the plurality of bit lines intersect each other, the method comprising:
controlling, for at least one of a plurality of non-selected word lines and a plurality of non-selected bit lines other than a selected word line and a selected bit line connected to a selected storage element, among the plurality of word lines and the plurality of bit lines, a potential applied thereto according to a line width of the non-selected bit lines and word lines.

19. The method according to claim 18, wherein
the word lines are arranged in the second direction, width of a first group of the word lines is the first width, width of a second group of the word lines is the second width, and the second group is arranged on both sides of the first group;
the bit lines are arranged in the first direction, width of a third group of the bit lines is the third width, width of a fourth group of the bit lines is the fourth width, and the fourth group is arranged on both sides of the third group,
the method further comprising:
in the word lines not connected to the selected storage element and the bit lines not connected to the selected storage element, performing a control so that a maximum value of voltages applied between the first group and the fourth group and between the second group and the third group is lower than a maximum value of voltages applied between the first group and the third group.

20. The method according to claim 18, wherein
the word lines are arranged in the second direction, width of a first group of the word lines is the first width, width of a second group of the word lines is the second width, and the second group is arranged on both sides of the first group;
the bit lines are arranged in the first direction, width of a third group of the bit lines is the third width, width of a fourth group of the bit lines is the fourth width, and the fourth group is arranged on both sides of the third group,
the method further comprising:
in the word lines not connected to the selected storage element and the bit lines not connected to the selected storage element, performing a control so that a maximum value of voltages applied between the second group and the fourth group is lower than a maximum value of voltages applied between the first group and the fourth group and between the second group and the third group.
